(19) United States
(12) Patent Application Publication
(10) Pub. No.: US 2014/0264294 A1
(43) Pub. Date: Sep. 18, 2014

(54) Three-dimensional Printing Surface Treatments

(71) Applicant: Elwha LLC, Bellevue, WA (US)

(72) Inventors: Pablos Holman, Seattle, WA (US); 3ric Johanson, Seattle, WA (US); Royce A. Levien, Lexington, MA (US); Mark A. Malamud, Seattle, WA (US)

(73) Assignee: Elwha LLC, Bellevue, WA (US)

(21) Appl. No.: 14/047,368

(22) Filed: Oct. 7, 2013

Related U.S. Application Data
(63) Continuation-in-part of application No. 13/839,935, filed on Mar. 15, 2013, now abandoned.

(51) Int. Cl. H01L 51/56; H01L 51/52

(52) U.S. Cl. CPC H01L 51/56; H01L 51/52
USPC 257/40; 438/34; 425/375; 29/729

(57) ABSTRACT

Systems and methods for applying a surface treatment to a product may implement operations including, but not limited to: depositing at least one first conductive element on at least one surface of the product; depositing at least one of one or more microcapsules or one or more organic light-emitting diodes (OLEDs) to at least partially electrically couple with the at least one first conductive element; and depositing at least one second conductive element to at least partially electrically couple with the at least one of one or more microcapsules or one or more OLEDs.

### CROSS-REFERENCE TO RELATED APPLICATIONS

If an Application Data Sheet (ADS) has been filed on the filing date of this application, it is incorporated by reference herein. Any applications claimed on the ADS for priority under 35 U.S.C. §§119, 120, 121, or 365(c), and any and all parent, grandparent, great-grandparent, etc. applications of such applications, are also incorporated by reference, including any priority claims made in those applications and any material incorporated by reference, to the extent such subject matter is not inconsistent herewith.

The present application is related to and/or claims the benefit of the earliest available effective filing date(s) from the following listed application(s) (the “Priority Applications”), if any, listed below (e.g., claims earliest available priority dates for other than provisional patent applications or claims benefits under 35 USC §119(e) for provisional patent applications, for any and all parent, grandparent, great-grandparent, etc. applications of the Priority Application(s)).

### PRIORITY APPLICATIONS

For purposes of the USPTO extra-statutory requirements, the present application constitutes a continuation-in-part of U.S. patent application Ser. No. 13/835,935 entitled SYSTEMS AND METHODS FOR THREE-DIMENSIONAL PRINTING, naming PABLOS HOLMAN, 3RIC JOHANSON, ROYCE A. LEVIEN, AND MARK A. MALAMUD as inventors, filed Mar. 14, 2013, which is currently co-pending or is an application of which a currently co-pending application is entitled to the benefit of the filing date.

In addition, the present application is related to the “Related Applications,” if any, listed below.

### RELATED APPLICATIONS

None.

The United States Patent Office (USPTO) has published a notice to the effect that the USPTO's computer programs require that patent applicants reference both a serial number and indicate whether an application is a continuation, continuation-in-part, or divisional of a parent application. Stephen G. Kunin, Benefit of Prior-Filed Application, USPTO Official Gazette Mar. 18, 2003. The USPTO further has provided forms for the Application Data Sheet which allow automatic loading of bibliographic data but which require identification of each application as a continuation, continuation-in-part, or divisional of a parent application. The present Applicant Entity (hereinafter “Applicant”) has provided above a specific reference to the application(s) from which priority is being claimed as recited by statute. Applicant understands that the statute is unambiguous in its specific reference language and does not require either a serial number or any characterization, such as “continuation” or “continuation-in-part,” for claiming priority to U.S. patent applications. Notwithstanding the foregoing, Applicant understands that the USPTO's computer programs have certain data entry requirements, and hence Applicant has provided designation(s) of a relationship between the present application and its parent application(s) as set forth above and in any ADS filed in this application, but expressly points out that such designation(s) are not to be construed in any way as any type of commentary and/or admission as to whether or not the present application contains any new matter in addition to the matter of its parent application(s).

If the listings of applications provided herein are inconsistent with the listings provided via an ADS, it is the intent of the Applicant to claim priority to each application that appears in the Priority Applications section of the ADS and to each application that appears in the Priority Applications section of this application.

All subject matter of the Priority Applications and the Related Applications and of any and all parent, grandparent, great-grandparent, etc. applications of the Priority Applications and the Related Applications, including any priority claims, is incorporated herein by reference to the extent such subject matter is not inconsistent herewith.

### BACKGROUND

Historically, what is now known as three-dimensional (3D) printing had been called rapid prototyping. Initially, rapid prototyping technologies used 3D lithography and laser sintering of lithographed layers. However, technologies have now shifted and 3D printing processes generally consist of the patterned deposition of small portions of material that are then fused together. Examples of currently used materials might include transparent materials, elastomeric materials, conductive materials, etc. This process is now referred to as 3D printing due to the analogous features of 2D printing (e.g. a 3D printer is configured to put down particles of material, like a 2D printer puts down particles of ink, except that in 3D printing, the particles are plastic or metal which may be fused with heat to form 3D structures).

The thrust of innovation to date has been in material advancement. For example, creation of new types of materials, improving layer resolution, and improving speed have been focuses as most 3D printers permit product fabrication with a single material at a time printers.

### SUMMARY

The present disclosures are directed to systems and methods for three-dimensional (3D) printing/rapid prototyping (collectively referred to as 3D printing herein).

The foregoing summary is illustrative only and is not intended to be in any way limiting. In addition to the illustrative aspects, embodiments, and features described above, further aspects, embodiments, and features will become apparent by reference.

### BRIEF DESCRIPTION OF THE FIGURES

FIG. 1 illustrates a 3D printing system.

FIG. 2 illustrates an electrophoretic system.

FIG. 3 illustrates an organic light-emitting diode system.

FIGS. 4-13 illustrate operations associated with surface treatments of a product.

FIG. 14 illustrates a photolithographic system.

### DETAILED DESCRIPTION

The illustrative embodiments described herein are not meant to be limiting. Other embodiments may be utilized, and other changes may be made, without departing from the spirit or scope of the subject matter presented here.

Various 3D printing methodologies exist today. Primarily, robots may construct a product via additive deposition of small amounts of a construction material or through progressive photo-curing of layers of photo-curable resin.

Current 3D printing methods may result in finished products having irregular surface finishes (e.g. surfaces that look resemble lumps of material melted together) that must be post-processed (e.g. sanding, buffing, surface treatments) to produce an acceptable end product palatable.

While 3D printing for has been contemplated for at-home use, it is also desirable to adapt 3D printing for mass manufacturing in light of the increased interest in automating manufacturing. Such developments in 3D printing may result in the transition of manufacturing operations typically reserved for manual labor to automated 3D printing installations.

A way to increase manufacturing via adaptation of 3D printing technologies is to effectively create a general purpose factory comprised of general purpose robots. As such, manufacturing can be carried out in a more generalized way and like software.

The driving force for using such adapted 3D printer technology is that it may reduce the cost for setting up a dedicated production line for a single product. For example, it may be the case that a general purpose line costs ten times that of a special purpose factory line, but the general purpose factory line can switch between products in five minutes rather than five months.

Such general purpose factories may include various universal processing machines. 3D printing may be thought of as “robot manufacturing.” For example, these machines may include with robotic arms with interchangeable heads (e.g. 3D printer heads), laser cutters, water jets, or other computer-controlled technologies that do not require machinists. A fundamental part of such manufacturing is robot arms that can move on several axes and equipped with a number of dedicated material deposition tips. For example, as shown in FIG. 1, the general purpose factory may have many movable general purpose robots 100. The robots 100 may include a multi-axis arm 101 and a print head 102. The print head 102 may be interchangeable with respect to the robot 100 such that multiple print heads 102 may be used with a common robot 100. The print head 102 may include a 3D material deposition tip 103 configured (e.g. sized, having a construction facilitating flow, etc.) for depositing a construction material. The 3D material deposition tip 103 may be provided construction material via a conduit 104 operably coupled to a 3D construction material storage vessel (not shown). Actuation of the multi-axis arm 101 may be controlled by a computing device (e.g. a desktop computer, laptop computer, tablet computer, smart phone, dedicated controller device, and the like) to position the multi-axis arm 101 in a position to deposit 3D construction material during fabrication of a 3D printing product (e.g. a toy,. For each 3D model forming the basis of a part to be fabricated, the computer device may compare a minimum clearance of the 3D model against a minimum resolution of a particular printing machine.

In such cases, the operation of such general-purpose machines may be configured simply by entering component data associated with a part to be manufactured. This is in contrast to other traditional manufacturing technologies which may require machinists for determining and planning how to make a part. A general purpose factory built from an adapted and modified 3D printer may eliminate a need for a dedicated machinist.

When a part is fabricated by a 3D printer, it may be constructed from a particulated (e.g. powdered or extruded) composition (e.g. thermoplastics or polymers (e.g. acrylonitrile butadiene styrene (ABS), polycarbonate (PC), polylactic acid (PLA), high density polyethylene (HDPE), PC/ABS, and polyphenylsulfone (PPSU)), metals and metal alloys) and may contain visible layers. For example, a computer controlled robot may construct a product via additive deposition of small amounts of a construction material which may bond with or be bonded to other prior depositions of the construction material. In such cases, some post-processing designed to provide a more finished product surface may be required. Such post-processing may include rubbing the item with acetone, physical smoothing, or painting.

In a dual component system, 3D printing machines may lay down a bed of powder and then print glue over the layer of powder to bind the powder to from a product layer. For every such “pixel” (i.e. powder and glue) the 3D print heads deposit glue and color. As such, the coloring of a finished product will necessarily be a function of the coloring of the power and then glue. Parts constructed in such a manner generally have degraded structural integrity (a function of the bond strength of the glue) and the result in a finish having dull colors.

Utilizing 3D printer technology whereby only a single component material is used and the component material is fused (e.g. via an application of heat), it is possible to get 3D shapes that could never be machined due to the impossibility of machining the shapes. While these products may have increased structural integrity they are generally mono-colored and may have unfinished surface characteristics.

To counter these deficiencies, various surface printing technologies may be applied to 3D printed products. For example, as shown in FIG. 2, an electrophoretic system 100B may be composed of di- or multi-chromatic microcapsules that, depending on electrostatic applications, may be configured to display different images. Such displays may not require power to hold their image, but instead only require power to change the image. As shown in FIG. 2, an electrophoretic system 100B may include an upper substrate later 101 (e.g. a plastic layer), a substantially transparent electrode layer 102 (e.g. indium-tin oxide traces, silver-titanium oxide traces), one or more transparent microcapsules 103, an electrode pixel layer 107, and a bottom support substrate 108. Each microcapsule 103 may include one or more positively charged (or negatively charged) white pigment elements 104, one or more negatively charged (or positively charged) black pigment elements 105, and a transparent or colored suspension medium 106 through which the charged pigment elements 104 and 105 may flow in response to a voltage applied across the electrode layers 102 and 107. Further, while shown as black and white pigment elements, the microcapsules 103 may have any pigment (e.g. a Red-Green-Blue (RGB) distribution) in order to impart multi-color display capabilities to the electrophoretic system 100B. Further, the suspension medium may also be colored providing an additional coloring component.

In systems having three or more pigments element types, the pigment elements may have relative charge gradations between respective colors. For example, a red pigment element may have a first charge, a green pigment may have a second charge greater than that of the first charge and a blue pigment element may have a third charge greater than the second charge.

In another embodiment the pigment elements may be polar in nature have a first end having a first color and a first charge (e.g. positive) and a second end having a second color and a second charge (e.g. negative). Application of a voltage to such polar pigment elements may orient the pigment elements in a given direction thereby imparting a color to the microcapsules.

It may be the case that the charged pigment elements may have varying degrees of charge such that their flow characteristics (rates, aggregations, etc.) may be more specifically configured by varying the voltage applied. For example, in the case of a microcapsule 103 including two charged pigment elements having the same charge polarity but having different charge strengths, it may be the case that an application of a first voltage level is only sufficient to migrate one of the charged particles but an application of a second voltage is sufficient to migrate both charged particles.

Such electrophoretic technologies may be incorporated into 3D printing technologies to facilitate 3D printing product surface treatments. For example, during fabrication of a 3D printing product (e.g. via a 3D printing robot 100), an exterior surface of the product may be at least partially covered with the electrophoretic system 100B using 3D printing technologies. For example, as shown in FIG. 1, a bottom support surface 108 may be an exterior surface of a 3D printing product generated by the 3D printing robot 100. Then, a 3D printing robot 100 may further deposit the components of the electrophoretic system 100B (i.e. the electrode pixel layer 107, the transparent microcapsules 103, the transparent electrode layer 102 and, optionally, a transparent upper substrate) using 3D printing material deposition technologies. Such a methodology could effectively be used to “paint” the exterior surface of a 3D printed product by covering the product with the electrophoretic system 100B and configuring the electrode layers 102 and 107. The coloring achieved by the configuration of the electrophoretic system 100B may be substantially static in that the coloring remains in the state specified by the electrode layers 102 and 107 even after the voltage across the electrode layers 102 and 107 is removed.

Such electrophoretic coatings may work well for coloring flat surfaces as well as irregular surfaces by building electrophoretic displays with layers of 3D printed microcapsules 103.

In another embodiment, one or more organic light-emitting diode (OLED) elements (e.g. particulate OLED compositions including organometallic chelates, poly(p-phenylene vinylene), polyfluorene poly(n-vinylcarbazole), and the like) may be disposed between electrode layers over an exterior surface of a 3D printed product. Referring to FIG. 3, an OLED system 100C may include OLEDs 109 disposed between a cathode 110 and an anode 111. The OLEDs 109 may include an organic emissive layer 112 and an organic conductive layer 113 where electrons 114 interact with holes 115 at the interface between the organic emissive layer 112 and an organic conductive layer 113 resulting in the generation of one or more photons.

The OLED system 100C may be disposed on the 3D printed product 108 in a manner similar to that described above with respect to the electrophoretic system 100B. For example, as shown in FIG. 3, a bottom support surface 108 may be an exterior surface of a 3D printing product 108 generated by the 3D printing robot 100. Then, a 3D printing robot 100 may further deposit the components of the OLED system 100C (i.e. the anode 111, the OLEDs 109, the cathode 110, and the like) using 3D printing material deposition technologies.

The cathode 110 and the anode 111 may be configured to power the OLEDS 109 in order to generate a displayed image on an exterior surface of a 3D printed product 108. The OLED system 100C may be an active system wherein the coloring of the OLED system 100C may be varied over time to cycle between static images to provide video display capabilities.

FIG. 4 and the following figures include various examples of operational flows, discussions and explanations may be provided with respect to the above-described exemplary environment of FIGS. 1-3. However, it should be understood that the operational flows may be executed in a number of other environments and contexts, and/or in modified versions of FIGS. 1-3. In addition, although the various operational flows are presented in the sequence(s) illustrated, it should be understood that the various operations may be performed in different sequential orders other than those which are illustrated, or may be performed concurrently.

Further, in the following figures that depict various flow processes, various operations may be depicted in a box-within-a-box manner. Such depictions may indicate that an operation in an internal box may comprise an optional example embodiment of the operational step illustrated in one or more external boxes. However, it should be understood that internal box operations may be viewed as independent operations separate from any associated external boxes and may be performed in any sequence with respect to all other illustrated operations, or may be performed concurrently.

FIG. 4 illustrates an operational procedure 400 for practicing aspects of the present disclosure including operations 402, 404, 406 and 408.

Operation 402 illustrates providing a product. For example, as shown in FIGS. 1-3, a product 108 may define a support surface for which it is desirable to modify one or surface characteristics to vary the appearance of the product 108. It may be the case that the product 108 is monochromatic but a multi-colored appearance is desired.

Operation 404 illustrates depositing at least one first conductive element on at least one surface of the product. For example, as shown in FIGS. 2 and 3, an electrode pixel layer 107 and/or an anode layer 111 may be deposited on (e.g. adhered to) a surface of the product 108.

Operation 406 illustrates depositing at least one of one or more microcapsules or one or more organic light-emitting diodes (OLEDs) to at least partially electrically couple with the at least one first conductive element. For example, as shown in FIGS. 2 and 3, one or more microcapsules 103 and/or OLEDs 109 may be deposited on the electrode pixel layer 107 or anode layer 111, respectively. Such disposal may result in electrically coupling the microcapsules 103 and/or OLEDs 109 to the electrode pixel layer 107 or anode layer 111 such that a voltage applied at the electrode pixel layer 107 or anode layer 111 (in combination with the electrode pixel layer 102 or cathode layer 110) will impart an electric field on the microcapsules 103 and/or OLEDs 109.

Operation 408 illustrates depositing at least one second conductive element to at least partially electrically couple with the at least one of one or more microcapsules or one or more OLEDs. For example, as shown in FIGS. 2 and 3, an electrode pixel layer 102 and/or a cathode layer 110 may be deposited the microcapsules 103 or the OLEDs 109, respectively. Such disposal may result in electrically coupling the microcapsules 103 and/or OLEDs 109 to the electrode pixel layer 102 or cathode layer 110 such that a voltage applied at the electrode pixel layer 102 or cathode layer 110 (in combination with the electrode pixel layer 107 or anode layer 111) will impart an electric field on the microcapsules 103 and/or OLEDs 109.

FIG. 5 further illustrates an operational procedure wherein operation 402 of operational flow 400 of FIG. 4 may include one or more additional operations. Additional operations may include operations 502 and/or 504.

Operation 502 illustrates providing a product produced via three-dimensional printing. For example, as shown in FIG. 1, robots 100 may include a multi-axis arm 101 and a print head 102. The print head 102 may include a 3D material deposition tip 103 configured (e.g. sized, having a characteristics facilitating flow, etc.) for depositing a construction material. The 3D material deposition tip 103 may be provided construction material via a conduit 104 operably coupled to a 3D construction material storage vessel (not shown). Actuation of the multi-axis arm 101 may be controlled by a computing device (e.g. a desktop computer, laptop computer, tablet computer, smart phone, dedicated controller device, and the like) to position the multi-axis arm 101 in a position to deposit 3D construction material during fabrication of a 3D printing product.

The robot 100 may construct a product via additive deposition of small amounts of a construction material (e.g. thermoplastics, metals, etc.) which may bond with or be bonded to other prior depositions of the construction material. In such cases, some post-processing designed to provide a more finished product surface may be required. Such post-processing may include rubbing the item with acetone, physical smoothing, or painting.

In a dual component system, 3D printing machines may lay down a bed of powder and then print glue over the layer of powder to bind the powder to from a product layer. For every such “pixel” (i.e. powder and glue) the 3D print heads deposit glue and color. As such, the coloring of a finished product will necessarily be a function of the coloring of the power and then glue. Parts constructed in such a manner generally have degraded structural integrity (a function of the bond strength of the glue) and the result in a finish having dull colors.

Utilizing 3D printer technology whereby only a single component material is used and the component material is fused (e.g. via an application of heat), it may be possible to obtain 3D shapes that could never be machined due to the impossibility of machining the shapes. While these products may have increased structural integrity they are generally mono-colored and may have unfinished surface characteristics.

Operation 504 illustrates providing a product produced via three-dimensional printing from only one three-dimensional printing construction material. For example, utilizing 3D printer technology whereby only a single component material is used and the component material is fused (e.g. via an application of heat), it may be possible to obtain 3D shapes that could never be machined due to the impossibility of machining the shapes. Such products may have increased structural integrity.

FIG. 6 further illustrates an operational procedure wherein operations 404, 406 and 408 of operational flow 400 of FIG. 4 may include one or more additional operations. Additional operations may include operations 602, 604 and 606.

Operation 602 illustrates depositing at least one first conductive element on at least one surface of the product via three-dimensional printing. For example, as shown in FIGS. 1-3, the 3D material deposition tip 103 may be provided construction material via a conduit 104 operably coupled to a 3D construction material storage vessel (not shown). Actuation of the multi-axis arm 101 may be controlled by a computing device (e.g. a desktop computer, laptop computer, tablet computer, smart phone, dedicated controller device, and the like) to position the multi-axis arm 101 in a position to deposit a conductive composition. The robot 100 may construct a conductive element via additive deposition of small amounts of a conductive composition (e.g. metals, carbon fiber, organic polymers, and the like) which may bond with or be bonded to other prior depositions of the conductive material and/or the surface of the product 108 to form the electrode pixel layer 107 or anode layer 111.

Operation 604 illustrates depositing at least one of one or more microcapsules or one or more organic light-emitting diodes (OLEDs) to at least partially electrically couple with the at least one first conductive element via three-dimensional printing. For example, as shown in FIGS. 1-3, the 3D material deposition tip 103 may be provided microcapsules 103 and/or OLEDs 109 via a conduit 104 operably coupled to a 3D construction material storage vessel (not shown). Actuation of the multi-axis arm 101 may be controlled by a computing device (e.g. a desktop computer, laptop computer, tablet computer, smart phone, dedicated controller device, and the like) to position the multi-axis arm 101 in a position to deposit the microcapsules 103 and/or the OLEDs 109. The robot 100 perform additive deposition of small amounts of the microcapsules 103 and/or the OLEDs 109 which may bond with or be bonded to prior depositions of the conductive material forming the electrode pixel layer 107 or anode layer 111.

Operation 606 illustrates depositing at least one second conductive element to at least partially electrically couple with the at least one of one or more microcapsules or one or more OLEDs via three-dimensional printing. For example, as shown in FIGS. 1-3, the 3D material deposition tip 103 may be provided conductive construction material via a conduit 104 operably coupled to a 3D construction material storage vessel (not shown). Actuation of the multi-axis arm 101 may be controlled by a computing device (e.g. a desktop computer, laptop computer, tablet computer, smart phone, dedicated controller device, and the like) to position the multi-axis arm 101 in a position to deposit a conductive composition (e.g. indium-tin oxide traces, silver-titanium oxide traces). The robot 100 may construct a conductive element via additive deposition of small amounts of conductive composition which may bond with or be bonded to prior depositions of the microcapsules 103 and/or the OLEDs 109 to form the electrode pixel layer 102 or cathode layer 110.

FIG. 7 further illustrates an operational procedure wherein operations 402 and 404 of operational flow 400 of FIG. 4 may include one or more additional operations. Additional operations may include operations 702 and/or 704.

Operation 702 illustrates providing a product produced via three-dimensional printing using a multi-axis robot including a first three-dimensional print head. For example, as shown in FIG. 1, robots 100 may include a multi-axis arm 101 and a print head 102. The print head 102 may include a 3D material deposition tip 103 configured for depositing the construction material forming the product 108. The 3D material deposition tip 103 may be provided construction material via a conduit 104 operably coupled to a 3D construction material storage vessel (not shown). Actuation of the multi-axis arm 101 may be controlled by a computing device (e.g. a desktop computer, laptop computer, tablet computer, smart phone, dedicated controller device, and the like) to position the multi-axis arm 101 in a position to deposit 3D construction material during fabrication of a 3D printing product.

Operation 704 illustrates depositing at least one first conductive element on at least one surface of the product using the multi-axis robot including a second three-dimensional print head. For example, as shown in FIG. 1, robots 100 may include a multi-axis arm 101 and a print head 102. The print head 102 may be interchangeable with respect to the robot 100 such that multiple print heads 102 may be used with the same robot 100 as used to construct the product 108 as described with respect to operation 702. The print head 102 may include a 3D material deposition tip 103 configured (e.g. sized, having a construction facilitating flow, etc.) for depositing a construction material. The 3D material deposition tip 103 may be provided conductive construction material via a conduit 104 operably coupled to a 3D construction material storage vessel (not shown). Actuation of the multi-axis arm 101 may be controlled by a computing device (e.g. a desktop computer, laptop computer, tablet computer, smart phone, dedicated controller device, and the like) to position the multi-axis arm 101 in a position to deposit a conductive composition. The robot 100 may construct a conductive element via additive deposition of small amounts of a conductive composition (e.g. metals, carbon fiber, organic polymers, and the like) which may bond with or be bonded to other prior depositions of the conductive material and/or the surface of the product 108 to form the electrode pixel layer 107 or anode layer 111

FIG. 8 further illustrates an operational procedure wherein operations 402 and 406 of operational flow 400 of FIG. 4 may include one or more additional operations. Additional operations may include operations 802 and/or 804.

Operation 802 illustrates providing a product produced via three-dimensional printing using a multi-axis robot including a first three-dimensional print head. For example, as shown in FIG. 1, robots 100 may include a multi-axis arm 101 and a print head 102. The print head 102 may include a 3D material deposition tip 103 configured for depositing the construction material forming the product 108. The 3D material deposition tip 103 may be provided construction material via a conduit 104 operably coupled to a 3D construction material storage vessel (not shown). Actuation of the multi-axis arm 101 may be controlled by a computing device (e.g. a desktop computer, laptop computer, tablet computer, smart phone, dedicated controller device, and the like) to position the multi-axis arm 101 in a position to deposit 3D construction material during fabrication of a 3D printing product.

Operation 804 illustrates depositing at least one of one or more microcapsules or one or more organic light-emitting diodes (OLEDs) to at least partially electrically couple with the at least one first conductive element using the multi-axis robot including a second three-dimensional print head. For example, as shown in FIG. 1, robots 100 may include a multi-axis arm 101 and a print head 102. The print head 102 may be interchangeable with respect to the robot 100 such that multiple print heads 102 may be used with the same robot 100 as used to construct the product 108 as described with respect to operation 802 (i.e. is interchangeable). The print head 102 may include a 3D material deposition tip 103 configured (e.g. sized, having a construction facilitating flow, etc.) for depositing a construction material. The 3D material deposition tip 103 may be provided microcapsules 103 and/or the OLEDs 109 via a conduit 104 operably coupled to a 3D construction material storage vessel (not shown). Actuation of the multi-axis arm 101 may be controlled by a computing device (e.g. a desktop computer, laptop computer, tablet computer, smart phone, dedicated controller device, and the like) to position the multi-axis arm 101 in a position to deposit the microcapsules 103 and/or the OLEDs 109. The robot 100 perform additive deposition of small amounts of the microcapsules 103 and/or the OLEDs 109 which may bond with or be bonded to prior depositions of the conductive material forming the electrode pixel layer 107 or anode layer 111.

FIG. 9 further illustrates an operational procedure wherein operations 402 and 408 of operational flow 400 of FIG. 4 may include one or more additional operations. Additional operations may include operations 902 and/or 904.

Operation 902 illustrates providing a product produced via three-dimensional printing using a multi-axis robot including a first three-dimensional print head. For example, as shown in FIG. 1, robots 100 may include a multi-axis arm 101 and a print head 102. The print head 102 may include a 3D material deposition tip 103 configured for depositing the construction material forming the product 108. The 3D material deposition tip 103 may be provided construction material via a conduit 104 operably coupled to a 3D construction material storage vessel (not shown). Actuation of the multi-axis arm 101 may be controlled by a computing device (e.g. a desktop computer, laptop computer, tablet computer, smart phone, dedicated controller device, and the like) to position the multi-axis arm 101 in a position to deposit 3D construction material during fabrication of a 3D printing product.

Operation 904 illustrates depositing at least one second conductive element to at least partially electrically couple with the at least one of one or more microcapsules or one or more OLEDs using the multi-axis robot including a second three-dimensional print head. For example, as shown in FIG. 1, robots 100 may include a multi-axis arm 101 and a print head 102. The print head 102 may be interchangeable with respect to the robot 100 such that multiple print heads 102 may be used with the same robot 100 as used to construct the product 108 as described with respect to operation 802 (i.e. is interchangeable). The print head 102 may include a 3D material deposition tip 103 configured (e.g. sized, having a construction facilitating flow, etc.) for depositing a construction material. The 3D material deposition tip 103 may be provided conductive construction material via a conduit 104 operably coupled to a 3D construction material storage vessel (not shown). Actuation of the multi-axis arm 101 may be controlled by a computing device (e.g. a desktop computer, laptop computer, tablet computer, smart phone, dedicated controller device, and the like) to position the multi-axis arm 101 in a position to deposit a conductive composition (e.g. indium-tin oxide traces, silver-titanium oxide traces). The robot 100 may construct a conductive element via additive deposition of small amounts of conductive composition which may bond with or be bonded to prior depositions of the microcapsules 103 and/or the OLEDs 109 to form the electrode pixel layer 102 or cathode layer 110.

FIG. 10 further illustrates an operational procedure wherein operation 406 of operational flow 400 of FIG. 4 may include one or more additional operations. Additional operations may include operations 1002, 1004 and/or 1006.

Operation 1002 illustrates depositing at least one microcapsule to at least partially electrically couple with the at least one first conductive element. For example, as shown in FIG. 2, one or more microcapsules 103 may be deposited on the electrode pixel layer 107. Such disposal may result in electrically coupling the microcapsules 103 to the electrode pixel layer 107 such that a voltage applied at the electrode pixel layer 107 (in combination with the electrode pixel layer 102) will impart an electric field on the microcapsules 103.

Operation 1004 illustrates depositing at least one microcapsule including one or more electrically charged pigment elements. For example, as shown in FIG. 2, Each microcapsule 103 may include one or more positively charged pigment elements 104 and/or one or more negatively charged pigment elements 105, and a transparent or colored suspension medium 106 through which the charged pigment elements 104 and 105 may flow in response to a voltage applied across the electrode layers 102 and 107.

Operation 1006 illustrates depositing at least one microcapsule including at least one pigment element having a positive charge and at least one pigment element having a negative charge. For example, as shown in FIG. 2, Each microcapsule 103 may include both positively charged pigment elements 104 and negatively charged pigment elements 105, and a transparent or colored suspension medium 106 through which the charged pigment elements 104 and 105 may flow in response to a voltage applied across the electrode layers 102 and 107.

FIG. 11 further illustrates an operational procedure wherein operational flow 400 of FIG. 10 may include one or more additional operations. Additional operations may include operations 1102 and/or 1104.

Operation 1102 illustrates applying a voltage across the first conductive element and the second conductive to configure the one or more electrically charged pigment elements. For example, as shown in FIG. 2, a voltage may be applied across the electrode layers 102 and 107. Each microcapsule 103 may include one or more positively charged pigment elements 104, one or more negatively charged pigment elements 105, and/or a transparent or colored suspension medium 106. Upon application of the voltage the across the electrode layers 102 and 107 charged pigment elements 104 and 105 may flow toward or away from the electrode layers 102 and 107 according to their charge in response to the voltage thereby changing the appearance of the exterior surface of the product 108. It may be the case that the charged pigment elements may have varying degrees of charge such that their flow characteristics (rates, aggregations, etc.) may be more specifically configured by varying the voltage applied. For example, in the case of a microcapsule 103 including two charged pigment elements having the same charge polarity but having different charge strengths, it may be the case that an application of a first voltage level is only sufficient to migrate one of the charged particles but an application of a second voltage is sufficient to migrate both charged particles.

Operation 1104 illustrates applying a voltage across the first conductive element and the second conductive to configure the one or more electrically charged pigment elements to display one or more images. For example, as shown in FIG. 2, a voltage may be applied across the electrode layers 102 and 107. Each microcapsule 103 may include one or more positively charged pigment elements 104, one or more negatively charged pigment elements 105, and/or a transparent or colored suspension medium 106. Upon application of the voltage the across the electrode layers 102 and 107 charged pigment elements 104 and 105 may flow toward or away from the electrode layers 102 and 107 according to their charge in response to the voltage thereby changing the appearance of the exterior surface of the product 108. In one embodiment, the entirety of a surface of the product 108 may be configured to have the same charged pigment elements placed in a viewable position within the microcapsules so as to present a monochromatic coloration of the surface of the product 108. In another embodiment, rather than having all microcapsules 103 configured in a common manner, it may be the case that the electrode layers 102 and 107 are selectively activated such that the microcapsules 103 are configured to generate an image. For example, multiple microcapsules 103 may be configured to have common charged pigment elements (e.g. charged pigment elements 104) placed in a viewable position within the microcapsules 103 while other microcapsules 103 may be configured to have the alternate charged pigment elements (e.g. charged pigment elements 104) placed in a viewable position within the microcapsules 103 to form an element of one more image elements (e.g. text, graphics, etc.). Further, the relative configurations of the various charged pigment elements may be varied over time to provide video display capabilities.

FIG. 12 further illustrates an operational procedure wherein operation 406 of operational flow 400 of FIG. 4 may include one or more additional operations. Additional operations may include operations 1202, 1204 and/or 1206.

Operation 1202 illustrates depositing at least one microcapsule including: at least one pigment element having a first pigment color and at least one pigment element having a second pigment color. For example, as shown in FIG. 2, Each microcapsule 103 may include both pigment elements 104 having a first color (e.g. white) and pigment elements 105 having a second color (e.g. black), and a transparent or colored suspension medium 106 through which the pigment elements 104 and 105 may flow in response to a voltage applied across the electrode layers 102 and 107.

Operation 1204 illustrates depositing at least one microcapsule including: at least one pigment element having a first pigment color, at least one pigment element having a second pigment color and at least one pigment element having a third pigment color. For example, as shown in FIG. 2, each microcapsule 103 may include pigment elements 104 having a first color (e.g. white), pigment elements 105 having a second color (e.g. black), and pigment elements (e.g. the suspension medium or another charged particle (not shown) suspended within the microcapsule) having a third color (e.g. red).

Operation 1206 illustrates depositing at least one microcapsule including: at least one pigment element having a substantially red pigment color, at least one pigment element having a substantially green color and at least one pigment element having a substantially blue pigment color. For example, as shown in FIG. 2, each microcapsule 103 may include pigment elements 104 having a first color (e.g. red), pigment elements 105 having a second color (e.g. green), and pigment elements (e.g. the suspension medium or another charged particle (not shown) suspended within the microcapsule) having a third color (e.g. blue).

FIG. 13 further illustrates an operational procedure wherein operation 406 of operational flow 400 of FIG. 4 may include one or more additional operations. Additional operations may include operations 1302. Further, FIG. 13 further illustrates an operational procedure wherein operational flow 400 of FIG. 4 may include one or more additional operations. Additional operations may include operations 1304 and/or 1306.

Operation 1302 illustrates depositing at least one of one or more microcapsules or one or more organic light-emitting diodes (OLEDs) to at least partially electrically couple with the at least one first conductive element. For example, as shown in FIG. 3, one or more OLEDs 109 may be deposited on the anode layer 111. Such disposal may result in electrically coupling the OLEDs 109 to anode layer 111 such that a voltage applied at the anode layer 111 (in combination with the cathode layer 110) will impart an electric field on the OLEDs 109.

Operation 1304 illustrates applying a voltage across the first conductive element and the second conductive to generate one or more photons via the one or more OLEDs. For example, as shown in FIG. 3, OLEDs 109 may be disposed between a cathode 110 and an anode 111. The OLEDs 109 may include an organic emissive layer 112 and an organic conductive layer 113. Upon application of a voltage across the cathode 110 and the anode 111, electrons 114 may interact with holes 115 at the interface between the organic emissive layer 112 and an organic conductive layer 113 resulting in the generation of one or more photons.

Operation 1306 illustrates applying a voltage across the first conductive element and the second conductive to generate one or more photons via the one or more OLEDs to display one or more images. For example, as shown in FIG. 3, OLEDs 109 may be disposed between a cathode 110 and an anode 111. The OLEDs 109 may include an organic emissive layer 112 and an organic conductive layer 113. Upon application of a voltage across the cathode 110 and the anode 111, electrons 114 may interact with holes 115 at the interface between the organic emissive layer 112 and an organic conductive layer 113 resulting in the generation of one or more photons. In one embodiment, the entirety of a surface of the product 108 may be configured to have the OLEDs 109 present a monochromatic coloration of the surface of the product 108. In another embodiment, rather than having all OLEDs 109 configured in a common manner, it may be the case that the cathode 110 and the anode 111 are selectively activated such that the OLEDs 109 are configured to generate an image. For example, multiple OLEDs 109 may be configured to have common photon emission characteristics may while other OLEDs 109 may be configured to have alternate photon emission characteristics to form an element of one more image elements (e.g. text, graphics, etc.). Further, the relative configurations of the various OLEDs 109 may be varied over time to provide video display capabilities.

Referring to FIG. 14, in another embodiment of a 3D printing system 200, a layer of photo-curable resin 201 (e.g. like that used for stereo lithography) may be disposed over a transparent plate 202. A projector device 203 (e.g. an LED panel display) may be positioned below the transparent plate 202 and configured to illuminate 204 the photo-curable resin 201 through the transparent plate 202 thereby curing a layer of the photo-curable resin 201. Over time, cured photo-curable resin defining a 3D printed product 205 may be drawn up (e.g. one millimeter) from the transparent plate 202 and another layer of photo-curable resin 201 may be illuminated 204 to construct a next layer of the 3D printing product 205. In order to generate coloring for a 3D printing product 205 produced according to such methodologies, the photo-curable resin 201 complex may include one or more photo-curable resins having a characteristic color (e.g. an RGB coloring scheme). As such, the photo-curable resins 201 having a characteristic color may be responsive to the colors of the illumination images 204 generated by the projector 203 thereby imparting color to one or more portions of the 3D printed product 205. Such a system 200 may allow for color control of the 3D printed product 205 according to the pixel resolution associated with the projector device.

In another embodiment, it may be the case that users may desire to create arbitrary objects based on arbitrary models. For example, users may desire to be able to take a photograph of an arbitrary 3D image, and then have methods and system that can look at the 3D image and reverse engineer it and figure out how it was made and construct one or more portions of the product via 3D printing technologies.

To facilitate such a process, a reverse engineering system may be employed to detect the components of an obtained image (e.g. an image captured from a cell phone) and search a reverse engineering library for one or more of those components (whether reproducible via 3D printing or not). For example, in one instance, if a user takes a picture of an action figure from the front, the system may prompt the user to also take a picture from the back. Then, the system may employ image recognition techniques to identify the components of the product. In a sense, such operations may be analogous to optical character recognition (OCR) for text.

A tool chain system may be provided such that one or more images of a 3D object may be obtained and deconstructed to get to a 3D component representation of the 3D object that appears in the image. If a given component is needed, the system may first check for a publicly available version of the component on a network (e.g. an open source internet website). If the component is not found, the system may search for a proprietary version of the component (e.g. on a retail website marketing such components (e.g. Amazon). Alternately, the system may suggest one or more modifications or substitutions that may be made for a proprietary component such that a component having comparable functionality may be obtained without payment or piracy. Also, the system might be capable of identifying one or more entities who may be authorized (e.g. a signatory to a license agreement) to provide a component or process associated with the component. Upon obtaining the component information from one or more sources, a 3D printing system may be employed to construct the various components of a desired product.

As a specific example, the above-described component recognition system may be applied to garment products. A user may be able to capture an image of an article of clothing and find out where to buy the product or what manufacturer produced the product.

In a exemplary embodiment, a retail company (e.g. Amazon) may operate based on image recognition and bar codes. The company may have employees who look up an imaged product and send the product to the user. Thus, a user could take a picture of a product (e.g. headphones), and the retail company would send that user a link to buy the product.

In another embodiment, a similar system would work for manufacturing a given product. For instance, a user may obtain a picture of product (e.g. headphones) and that user may print the product on a personal 3D printing machine. In this case, registry data may be maintained for products and their components. Product data may include information associated with a designer/rights holder of a product as well as what product components can and cannot be printed. For instance, it may be the case that a user may be authorized to print a shell portion of a set of headphones but not the electronic speaker elements. In such a case, a link would be provided from which the consumer could buy the speaker elements themselves or the rights to reproduce such speaker elements.

Returning to the production of articles of clothing, an article of clothing may be made to conform to the body of a user where some areas may be made more or less flexible or insulated according to a user's physique. Such products may be produced on computer controlled looms configured to custom knit clothes. Ultimately, a user may determine that a given clothing product fits properly and the remainder of their clothing may be manufactured accordingly. In other examples, a generalized production machine may be configured for building tires, jeans, and pasta merely by changing a few process specific elements (e.g. a 3D printing deposition head or photo-curable resin) to begin producing an entirely new product. In such cases, the above described systems and methods associated with 3D printing may be employed.

Further, it may be the case that enforcement of product manufacturing authorization by legal processes may difficult and expensive. For instance, large corporate entities producing large lots of proprietary products may effectively combat unauthorized reproduction via legal processes (e.g. negotiations, lawsuits, etc.). However, the distributed use of 3D printers by individual users to create unauthorized products may render such broad legal mechanisms ineffective. If users of 3D printers were teenagers in their basement, then it would be impractical to send lawyers after all of them. As such, in certain instances, digital rights management (DRM) may be used to regulate the usage of an individualized 3D printing system.

A goal of the above described systems and methods may be to create a matrix of all manufacturing that exists in world, and then identify what portions of that manufacturing currently performed manually could be automated. For example processes where 3D printing can be employed can be incorporated into general purpose factories. Therefore, some custom manufacturing processes may be eliminated. For example, metal spinning, such as pushing metal over spinning mold, is generally done by hand by machinists. Haptic feedback, gesture recognition or image recognition devices may be configured to record what metal spinners “feel” and “see.” Once such tactile and visual motions are captured, a robotic production system may be programmed to perform such activities. More specifically, time, pressure, acceleration, and deceleration rates may be measured with the end result being a metal spinning machine. Such tactile and visual capture operations may be applied to any number of manual operations. For example, movements by a seamstress may be captured and, in conjunction with a cooperative sensor system for determining the stretching and movement of fabric, hand stitching operations may be automated.

Those having skill in the art will recognize that the state of the art has progressed to the point where there is little distinction left between hardware and software implementations of aspects of systems; the use of hardware or software is generally (but not always, in that in certain contexts the choice between hardware and software can become significant) a design choice representing cost vs. efficiency tradeoffs. Those having skill in the art will appreciate that there are various vehicles by which processes and/or systems and/or other technologies described herein can be effected (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; alternatively, if flexibility is paramount, the implementer may opt for a mainly software implementation; or, yet again alternatively, the implementer may opt for some combination of hardware, software, and/or firmware. Hence, there are several possible vehicles by which the processes and/or devices and/or other technologies described herein may be effected, none of which is inherently superior to the other in that any vehicle to be utilized is a choice dependent upon the context in which the vehicle will be deployed and the specific concerns (e.g., speed, flexibility, or predictability) of the implementer, any of which may vary. Those skilled in the art will recognize that optical aspects of implementations will typically employ optically-oriented hardware, software, and or firmware.

The foregoing detailed description has set forth various embodiments of the devices and/or processes via the use of block diagrams, flowcharts, and/or examples. Insofar as such block diagrams, flowcharts, and/or examples contain one or more functions and/or operations, it will be understood by those within the art that each function and/or operation within such block diagrams, flowcharts, or examples can be implemented, individually and/or collectively, by a wide range of hardware, software, firmware, or virtually any combination thereof. In one embodiment, several portions of the subject matter described herein may be implemented via Application Specific Integrated Circuits (ASICs), Field Programmable Gate Arrays (FPGAs), digital signal processors (DSPs), or other integrated formats. However, those skilled in the art will recognize that some aspects of the embodiments disclosed herein, in whole or in part, can be equivalently implemented in integrated circuits, as one or more computer programs running on one or more computers (e.g., as one or more programs running on one or more computer systems), as one or more programs running on one or more processors (e.g., as one or more programs running on one or more microprocessors), as firmware, or as virtually any combination thereof, and that designing the circuitry and/or writing the code for the software and or firmware would be well within the skill of one of skill in the art in light of this disclosure. In addition, those skilled in the art will appreciate that the mechanisms of the subject matter described herein are capable of being distributed as a program product in a variety of forms, and that an illustrative embodiment of the subject matter described herein applies regardless of the particular type of signal bearing medium used to actually carry out the distribution. Examples of a signal bearing medium include, but are not limited to, the following: a recordable type medium such as a floppy disk, a hard disk drive, a Compact Disc (CD), a Digital Video Disk (DVD), a digital tape, a computer memory, etc.; and a transmission type medium such as a digital and/or an analog communication medium (e.g., a fiber optic cable, a waveguide, a wired communications link, a wireless communication link, etc.).

In a general sense, those skilled in the art will recognize that the various aspects described herein which can be implemented, individually and/or collectively, by a wide range of hardware, software, firmware, or any combination thereof can be viewed as being composed of various types of “electrical circuitry.” Consequently, as used herein “electrical circuitry” includes, but is not limited to, electrical circuitry having at least one discrete electrical circuit, electrical circuitry having at least one integrated circuit, electrical circuitry having at least one application specific integrated circuit, electrical circuitry forming a general purpose computing device configured by a computer program (e.g., a general purpose computer configured by a computer program which at least partially carries out processes and/or devices described herein, or a microprocessor configured by a computer program which at least partially carries out processes and/or devices described herein), electrical circuitry forming a memory device (e.g., forms of random access memory), and/or electrical circuitry forming a communications device (e.g., a modem, communications switch, or optical-electrical equipment). Those having skill in the art will recognize that the subject matter described herein may be implemented in an analog or digital fashion or some combination thereof.

Those skilled in the art will recognize that it is common within the art to describe devices and/or processes in the fashion set forth herein, and thereafter use engineering practices to integrate such described devices and/or processes into data processing systems. That is, at least a portion of the devices and/or processes described herein can be integrated into a data processing system via a reasonable amount of experimentation. Those having skill in the art will recognize that a typical data processing system generally includes one or more of a system unit housing, a video display device, a memory such as volatile and non-volatile memory, processors such as microprocessors and digital signal processors, computational entities such as operating systems, drivers, graphical user interfaces, and applications programs, one or more interaction devices, such as a touch pad or screen, and/or control systems including feedback loops and control motors (e.g., feedback for sensing position and/or velocity; control motors for moving and/or adjusting components and/or quantities). A typical data processing system may be implemented utilizing any suitable commercially available components, such as those typically found in data computing/communication and/or network computing/communication systems.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

While particular aspects of the present subject matter described herein have been shown and described, it will be apparent to those skilled in the art that, based upon the teachings herein, changes and modifications may be made without departing from the subject matter described herein and its broader aspects and, therefore, the appended claims are to encompass within their scope all such changes and modifications as are within the true spirit and scope of the subject matter described herein. Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

What is claimed is:

1. A method for surface treatment of a product comprising:
providing a product;
depositing at least one first conductive element on at least one surface of the product;
depositing at least one of one or more microcapsules or one or more organic light-emitting diodes (OLEDs) to at least partially electrically couple with the at least one first conductive element; and
depositing at least one second conductive element to at least partially electrically couple with the at least one of one or more microcapsules or one or more OLEDs.

2. The method of claim 1, wherein the providing a product includes:
providing a product produced via three-dimensional printing.

3. The method of claim 2, wherein the providing a product produced via three-dimensional printing includes:
providing a product produced via three-dimensional printing from only one three-dimensional printing construction material.

4. The method of claim 1, wherein the depositing at least one first conductive element on at least one surface of the product includes:
depositing at least one first conductive element on at least one surface of the product via three-dimensional printing.

5. The method of claim 1, wherein the depositing at least one of one or more microcapsules or one or more organic light-emitting diodes (OLEDs) to at least partially electrically couple with the at least one first conductive element includes:
depositing at least one of one or more microcapsules or one or more organic light-emitting diodes (OLEDs) to at least partially electrically couple with the at least one first conductive element via three-dimensional printing.

6. The method of claim 1, wherein the depositing at least one second conductive element to at least partially electrically couple with the at least one of one or more microcapsules or one or more OLEDs includes:
depositing at least one second conductive element to at least partially electrically couple with the at least one of one or more microcapsules or one or more OLEDs via three-dimensional printing.

7. The method of claim 1,
wherein the providing a product produced via three-dimensional printing includes:
providing a product produced via three-dimensional printing using a multi-axis robot including a first three-dimensional print head; and
wherein the depositing at least one first conductive element on at least one surface of the product includes:
depositing at least one first conductive element on at least one surface of the product using the multi-axis robot including a second three-dimensional print head.

8. The method of claim 1,
wherein the providing a product produced via three-dimensional printing includes:
providing a product produced via three-dimensional printing using a multi-axis robot including a first three-dimensional print head; and
wherein the depositing at least one of one or more microcapsules or one or more organic light-emitting diodes (OLEDs) to at least partially electrically couple with the at least one first conductive element includes:
depositing at least one of one or more microcapsules or one or more organic light-emitting diodes (OLEDs) to at least partially electrically couple with the at least one first conductive element using the multi-axis robot including a second three-dimensional print head.

9. The method of claim 1,
wherein the providing a product produced via three-dimensional printing includes:
providing a product produced via three-dimensional printing using a multi-axis robot including a first three-dimensional print head; and
wherein the depositing at least one second conductive element to at least partially electrically couple with the at least one of one or more microcapsules or one or more OLEDs includes:
depositing at least one second conductive element to at least partially electrically couple with the at least one of one or more microcapsules or one or more OLEDs using the multi-axis robot including a second three-dimensional print head.

10. The method of claim 1, wherein the depositing at least one of one or more microcapsules or one or more organic light-emitting diodes (OLEDs) to at least partially electrically couple with the at least one first conductive element includes:
depositing at least one microcapsule to at least partially electrically couple with the at least one first conductive element.

11. The method of claim 10, wherein the depositing at least one microcapsule to at least partially electrically couple with the at least one first conductive element includes:
depositing at least one microcapsule including one or more electrically charged pigment elements.

12. The method of claim 11, wherein the depositing at least one microcapsule to at least partially electrically couple with the at least one first conductive element includes:
depositing at least one microcapsule including at least one pigment element having a positive charge and at least one pigment element having a negative charge.

13. The method of claim 11, further comprising:
applying a voltage across the first conductive element and the second conductive to configure the one or more electrically charged pigment elements.

14. The method of claim 13, wherein the applying a voltage across the first conductive element and the second conductive to configure the one or more electrically charged pigment elements includes:
applying a voltage across the first conductive element and the second conductive to configure the one or more electrically charged pigment elements to display one or more images.

15. The method of claim 10, wherein the depositing at least one microcapsule to at least partially electrically couple with the at least one first conductive element includes:
depositing at least one microcapsule including: at least one pigment element having a first pigment color and at least one pigment element having a second pigment color.

16. The method of claim 15, wherein the depositing at least one microcapsule including: at least one pigment element having a first pigment color and at least one pigment element having a second pigment color further includes:
depositing at least one microcapsule including: at least one pigment element having a first pigment color, at least one pigment element having a second pigment color and at least one pigment element having a third pigment color.

17. The method of claim 16, wherein the depositing at least one microcapsule including: at least one pigment element having a first pigment color, at least one pigment element having a second pigment color and at least one pigment element having a third pigment color includes:
depositing at least one microcapsule including: at least one pigment element having a substantially red pigment color, at least one pigment element having a substantially green color and at least one pigment element having a substantially blue pigment color.

18. The method of claim 1, wherein the depositing at least one microcapsule to at least partially electrically couple with the at least one first conductive element includes:
depositing one or more OLEDs to at least partially electrically couple with the at least one first conductive element.

19. The method of claim 18, further comprising:
applying a voltage across the first conductive element and the second conductive to generate one or more photons via the one or more OLEDs.

20. The method of claim 19, wherein the applying a voltage across the first conductive element and the second conductive to generate one or more photons via the one or more OLEDs includes:
applying a voltage across the first conductive element and the second conductive to generate one or more photons via the one or more OLEDs to display one or more images.

21. A system for applying a surface treatment to a product comprising:
circuitry for depositing at least one first conductive element on at least one surface of the product;
circuitry for depositing at least one of one or more microcapsules or one or more organic light-emitting diodes (OLEDs) to at least partially electrically couple with the at least one first conductive element; and
circuitry for depositing at least one second conductive element to at least partially electrically couple with the at least one of one or more microcapsules or one or more OLEDs.

22. The system of claim 21, wherein the circuitry for depositing at least one first conductive element on at least one surface of the product includes:
circuitry for depositing at least one first conductive element on at least one surface of the product via three-dimensional printing.

23. The system of claim 21, wherein the circuitry for depositing at least one second conductive element to at least partially electrically couple with the at least one of one or more microcapsules or one or more OLEDs includes:
circuitry for depositing at least one second conductive element to at least partially electrically couple with the at least one of one or more microcapsules or one or more OLEDs via three-dimensional printing.

24. The system of claim 21, wherein the circuitry for depositing at least one second conductive element to at least partially electrically couple with the at least one of one or more microcapsules or one or more OLEDs includes:
circuitry for depositing at least one second conductive element to at least partially electrically couple with the at least one of one or more microcapsules or one or more OLEDs via three-dimensional printing.

25. A surface-treated product comprising:
at least one first conductive element disposed on at least one surface of the product;
at least one of one or more microcapsules or one or more organic light-emitting diodes (OLEDs) at least partially electrically coupled with the at least one first conductive element; and
at least one second conductive element at least partially electrically coupled with the at least one of one or more microcapsules or one or more OLEDs.

26. The surface-treated product of claim 25, wherein the product is produced via three-dimensional printing.

27. The surface-treated product of claim 25, wherein the at least one first conductive element is disposed on at least one surface of a product via three-dimensional printing.

28. The surface-treated product of claim 25, wherein the at least one of one or more microcapsules or one or more organic light-emitting diodes (OLEDs) are at least partially electrically coupled with the at least one first conductive element via three-dimensional printing.

29. The surface-treated product of claim 25, wherein the at least one second conductive element at is least partially electrically coupled with the at least one of one or more microcapsules or one or more OLEDs via three-dimensional printing.

30. A surface treatment system comprising:
one or more robotic devices; and
one or more interchangeable three-dimensional print heads operably couplable to the one or more robotic devices and configured for:
depositing at least one first conductive element on at least one surface of the product;
depositing at least one of one or more microcapsules or one or more organic light-emitting diodes (OLEDs) to at least partially electrically couple with the at least one first conductive element; and
depositing at least one second conductive element to at least partially electrically couple with the at least one of one or more microcapsules or one or more OLEDs.
